(19) United States
(12) Patent Application Publication
(10) Pub. No.: US 2011/0155437 A1
(43) Pub. Date: Jun. 30, 2011

(54) PRINTED CIRCUIT BOARD

(75) Inventors: PING WANG, Shenzhen City (CN); WEI-DONG CHEN, Shenzhen City (CN)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/758,613

(22) Filed: Apr. 12, 2010

(30) Foreign Application Priority Data
Dec. 31, 2009 (CN) 200920319295.3

(51) Int. Cl. H05K 1/11

(52) U.S. Cl. 174/261

(57) ABSTRACT

A printed circuit board includes a signal trace, capable of transmitting signal, and a pad. The pad is electronically connected to the signal trace. The pad is placed on an external surface of the printed circuit board. The pad includes a body and an extending portion extending from the body. The body is configured to weld an electronic element. The extending portion defines a first edge and a second edge parallel to the first edge. The length of the first edge is greater than that of the second edge. The extending portion is connected to the body at the first edge, and the extending portion is connected to the signal trace at the second edge.

### BACKGROUND

1. Technical Field

The present disclosure relates to printed circuit boards, especially to a printed circuit board having high signal transmission quality.

2. Description of Related Art

A plurality of signal traces and pads are placed on a printed circuit board. Electronic elements, such as resistors or capacitors, are welded on the pads. Generally, impedance mismatching may occur between a pad and a signal trace connected to the pad which can cause signal reflection and affect signal transmission quality of the printed circuit board.

### BRIEF DESCRIPTION OF THE DRAWINGS

FIG. 1 is a sketch view of a printed circuit board in accordance with an embodiment of the present disclosure, the print circuit board including a pad.

FIG. 2 is a sketch view of a printed circuit board in accordance with an embodiment of the present disclosure having pads of FIG. 1.

FIG. 3 is a sketch view of a printed circuit board in accordance with an embodiment of the present disclosure, the print circuit board including a pad.

FIG. 4 is a sketch view of a printed circuit board in accordance with an embodiment of the present disclosure having pads of FIG. 3.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

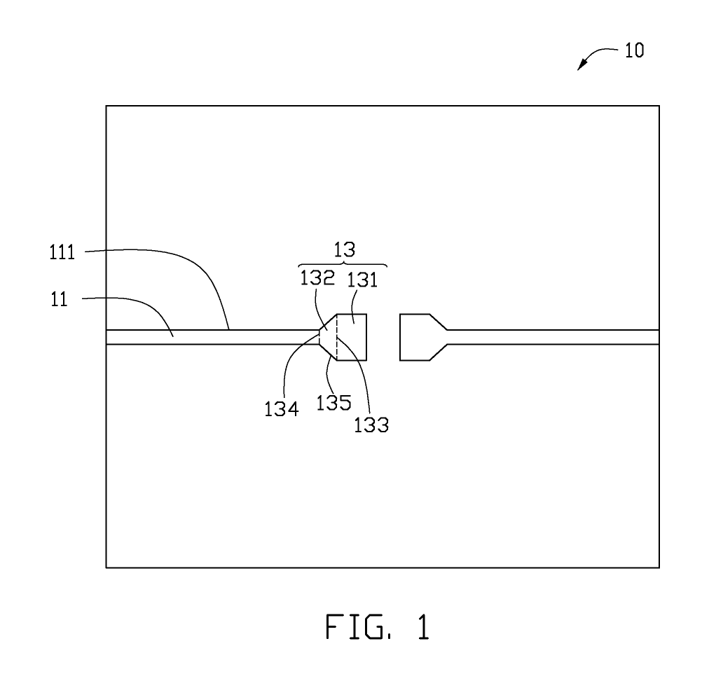

Referring to FIG. 1, a printed circuit board (PCB) 10 includes two signal traces 11 and two pads 13 connected between the two signal traces 11. An electronic element (not shown), such as a resistor or capacitor, is welded between the two pads 13 to connect the two signal traces 11.

Each pad 13 includes a body 131 and an extending portion 132 extending from the body 131. The body 131 is rectangular. The extending portion 132 can be an isosceles trapezoid-shaped. The extending portion 132 includes a first edge 133, a second edge 134 parallel to the first edge 133, and two linear side edges 135 connected between the first edge 133 and the second edge 134. The length of the second edge 134 is less than that of the first edge 133. The first edge 133 serves as a side of the body 131. The second edge 134 is connected to the signal trace 11. The signal trace 11 includes two parallel external edges 111. Distance between the two parallel external edges 111 is equal to the length of the second edge 134. The extending portion 132 gradually and uniformly narrows from the first edge 133 to the second edge 134.

Impedance from the signal trace 11 to the pad 13 or from the pad 13 to the signal trace 11 varies gradually due to the extending portion 132, thereby impedance mismatching is minimized and gradual thus minimizing signal reflection.

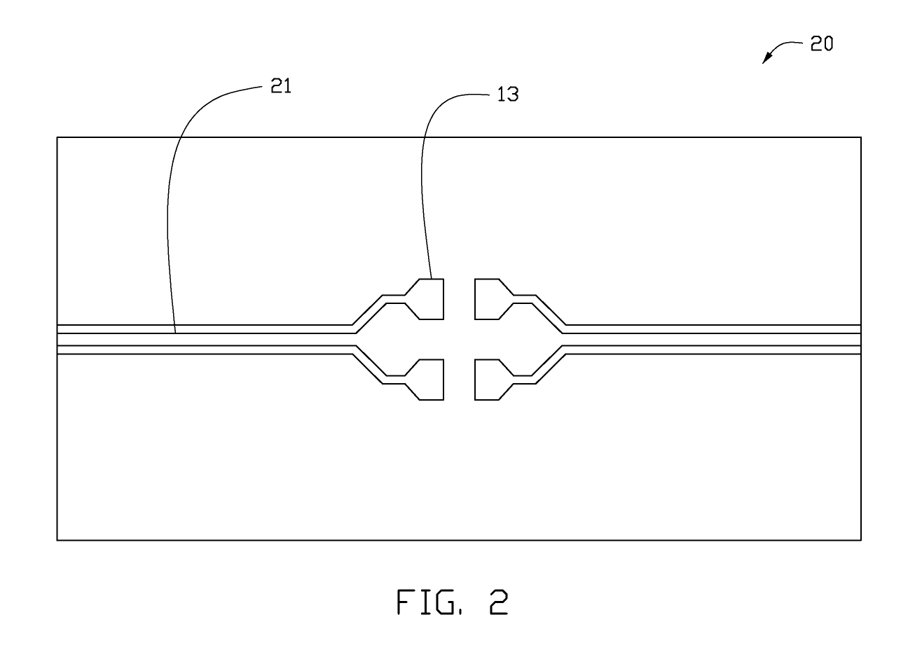

Referring to FIG. 2, a PCB 20 includes two signal traces 21 for transmission of differential signals. The pads 13 shown in FIG. 1 are applied with the two signal traces 21.

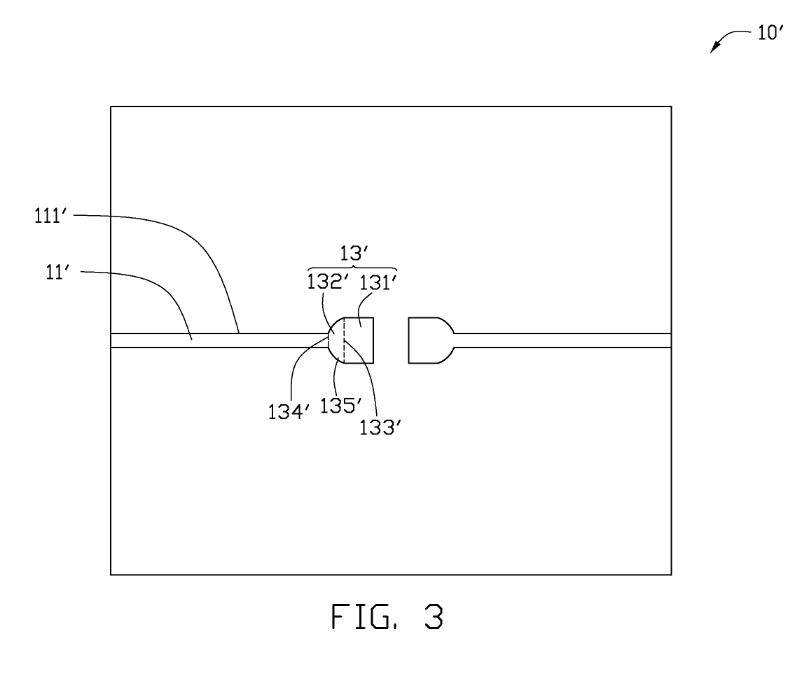

Referring to FIG. 3, a PCB 10′ includes two signal traces 11′ and two pads 13′ connected between the two signal traces 11′. An electronic element (not shown), such as a resistor or capacitor, is welded between the two pads 13′ to connect the two signal traces 11′.

Each pad 13′ includes a body 131′ and an extending portion 132′ extending from the body 131′. The body 131′ is rectangular. The extending portion 132′ includes a first edge 133′, a second edge 134′ parallel to the first edge 133′, and two arc-shaped side edges 135′ connected between the first edge 133′ and the second edge 134′. The length of the second edge 134′ is less than that of the first edge 133′. The first edge 133′ is as a side of the body 131′. The second edge 134′ is connected to the signal trace 11′. The signal trace 11′ includes two parallel external edges 111′. Distance between the two parallel external edges 111′ is equal to the length of the second edge 134′. The extending portion 132′ gradually narrows from the first edge 133′ to the second edge 134′. The extending portion 132′ is substantially shaped like a truncated semicircle.

Impedance from the signal trace 11′ to the pad 13′ or from the pad 13′ to the signal trace 11′ varies gradually due to the extending portion 132′, thereby reducing signal reflection as in the first embodiment.

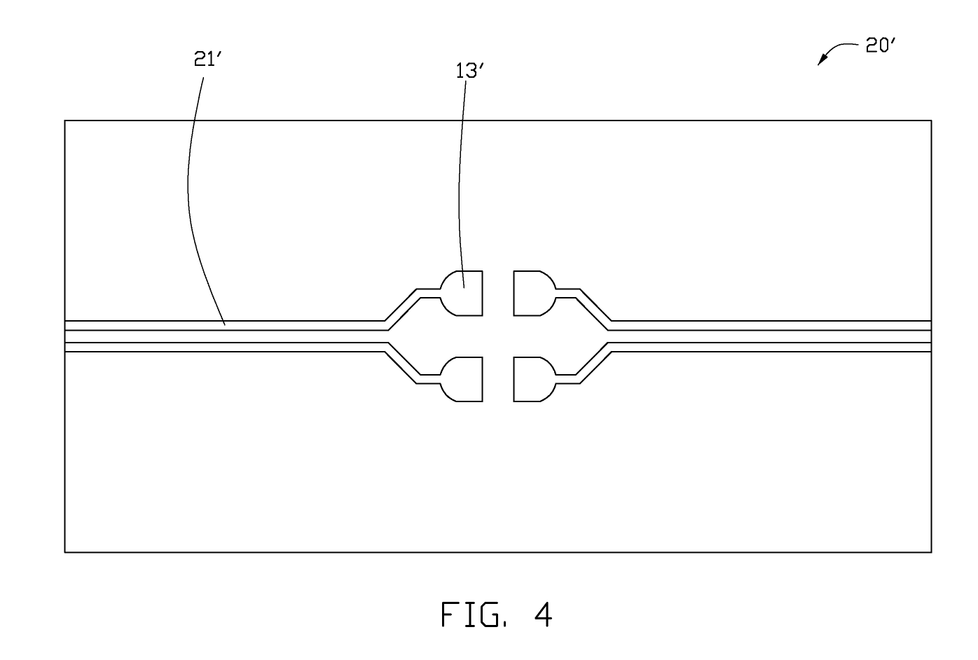

Referring to FIG. 4, a PCB 20′ includes two signal traces 21′ for transmission of differential signals. Pads 13′ shown in FIG. 3 are applied in the two signal traces 21′.

It is to be understood, however, that even though numerous characteristics and advantages of the present invention have been set forth in the foregoing description, together with details of the structure and function of the disclosure, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A printed circuit board, comprising:
a signal trace capable of transmitting signal; and
a pad electronically connected to the signal trace, the pad comprising a body and an extending portion extending from the body, the body configured to be welded to an electronic element, the extending portion defining a first edge and a second edge parallel to the first edge, wherein the length of the first edge is greater than that of the second edge, the extending portion is connected to the body at the first edge, and the extending portion is connected to the signal trace at the second edge.

2. The printed circuit board of claim 1, wherein the extending portion is trapezoid-shaped.

3. The printed circuit board of claim 2, wherein the extending portion is isosceles trapezoid-shaped.

4. The printed circuit board of claim 1, wherein the extending portion comprises two external edges connected to corresponding ends of the first edge and the second edge, each external edge is curvilinear.

5. The printed circuit board of claim 1, wherein each external edge is arc-shaped.

6. The printed circuit board of claim 5, wherein the extending portion has a substantially truncated semicircle-shape.

7. The printed circuit board of claim 1, wherein the extending portion comprises two side edges connected to corresponding ends of the first edge and the second edge, each side edge is linear.

8. The printed circuit board of claim 1, wherein the body is rectangular.

9. The printed circuit board of claim 8, wherein the first edge serves as a side of the body.

10. The printed circuit board of claim 1, wherein the signal trace comprises two parallel external edges, and a distance between the two external edges is equal to the length of the second edge.

11. A printed circuit board, comprising:
a signal trace capable of transmitting signal; and
a pad electronically connected to the signal trace, the pad placed on an external surface of the printed circuit board, the pad comprising a body and an extending portion extending from the body, the body configured to be welded to an electronic element, the extending portion defining a first edge and a second edge parallel to the first edge, wherein the length of the first edge is greater than that of the second edge, the extending portion is connected to the body at the first edge, and the extending portion is connected to the signal trace at the second edge; the extending portion comprises two side edges connected to corresponding ends of the first edge and the second edge; the extending portion gradually narrows from the first edge to the second edge.

12. The printed circuit board of claim 11, wherein the extending portion is trapezoid-shaped.

13. The printed circuit board of claim 12, wherein the extending portion is isosceles trapezoid-shaped.

14. The printed circuit board of claim 11, wherein the extending portion comprises two external edges connected to corresponding ends of the first edge and the second edge, each external edge is curvilinear.

15. The printed circuit board of claim 11, wherein each external edge is arc-shaped.

16. The printed circuit board of claim 15, wherein the extending portion has a substantially truncated semicircle-shape.

17. The printed circuit board of claim 11, wherein each side edge is linear.

18. The printed circuit board of claim 11, wherein the body is rectangular.

19. The printed circuit board of claim 18, wherein the first edge serves as a side of the body.

20. The printed circuit board of claim 11, wherein the signal trace comprises two parallel external edges, and a distance between the two external edges is equal to the length of the second edge.
